(19) United States
(12) Patent Application Publication
(10) Pub. No.: US 2012/0015525 A1
(43) Pub. Date: Jan. 19, 2012

(54) METHOD OF CLEANING A THIN FILM FORMING APPARATUS, THIN FILM FORMING METHOD, AND THIN FILM FORMING APPARATUS

(75) Inventors: Atsushi ENDO, Nirasaki-City (JP); Kazumi KUBO, Oshu-shi (JP); Satoshi MIZUNAGA, Nirasaki-shi (JP)

(73) Assignee: TOKYO ELECTRON LIMITED, Tokyo (JP)

(21) Appl. No.: 13/183,582

(22) Filed: Jul. 15, 2011

(30) Foreign Application Priority Data
Jul. 15, 2010 (JP) 2010-161085
May 31, 2011 (JP) 2011-121821

(51) Int. Cl. H01L 21/31; B08B 5/00; C23C 16/52

(52) U.S. Cl. 438/758; 118/715; 134/31; 257/E21.24

(57) ABSTRACT

A method of cleaning a thin film forming apparatus, for removing deposits adhering to an inside thereof after supplying a film-forming gas into a reaction chamber to form a amorphous carbon film on a workpiece, includes a heating operation of heating at least one of an inside of the reaction chamber and an inside of an exhaust pipe connected to the reaction chamber to a predetermined temperature; and a removing operation of supplying a cleaning gas containing oxygen gas and hydrogen gas into at least one of the inside of the reaction chamber and the inside of the exhaust pipe heated in the heating operation, heating the cleaning gas to the predetermined temperature to activate the oxygen gas and the hydrogen gas contained in the cleaning gas, and thereafter removing the deposits adhering to the inside of the thin film forming apparatus by the oxygen gas and the hydrogen gas activated.

### CROSS-REFERENCE TO RELATED PATENT APPLICATION

This application claims the benefit of Japanese Patent Application Nos. 2010-161085 and 2011-121821, filed on Jul. 15, 2010 and May 31, 2011, respectively, in the Japan Patent Office, the disclosure of which is incorporated herein in their entirety by reference.

### TECHNICAL FIELD

The present disclosure relates to a method of cleaning a thin film forming apparatus, a thin film forming method, and a thin film forming apparatus.

### BACKGROUND

In a manufacturing process of semiconductor devices or the like, an inter-layer insulation film with low dielectric constant has been developed in order to reduce the resistance or capacitance of a wiring part. Use of an amorphous carbon film as the inter-layer insulation film with low dielectric constant has been under review. The amorphous carbon film has been used as a hard mask in an integrated circuit manufacturing process.

For example, as disclosed in U.S. Pat. No. 5,981,000, such an amorphous carbon film is formed by supplying a cyclic hydrocarbon gas into a chamber of a single-wafer plasma CVD (Chemical Vapor Deposition) apparatus and generating plasma within the chamber. Since coverage performance grows worse when forming the amorphous carbon film with the single-wafer plasma CVD apparatus, use of a batch-type CVD apparatus in forming the amorphous carbon film has been under investigation.

However, if the amorphous carbon film is formed with the CVD apparatus, deposits such as reaction products or reaction byproducts adhere to the inside of the CVD apparatus, for example, the inner wall of a reaction tube. In particular, the deposits tend to adhere to low-temperature parts arranged outside a processing area, for example, an exhaust pipe. If the formation processing of the amorphous carbon film is performed with the deposits adhering to the inside of the CVD apparatus, particles are generated as the deposits are increased and peeled off. Adherence of the particles to workpieces may reduce the throughput of semiconductor devices (products) manufactured. In view of this, a review has been conducted on a dry cleaning method in which the deposits adhering to the inside of the CVD apparatus are removed by supplying a cleaning gas into the reaction tube heated to a predetermined temperature by a heater.

It is quite difficult and time-consuming for the dry cleaning method to remove the deposits adhering to low-temperature parts arranged outside a processing area such as the deposits adhering to an exhaust pipe. Although it is conceivable to use oxygen radicals or ozone generated by a plasma generator in order to remove the deposits adhering to an exhaust pipe, this may increase the initial cost. For this reason, maintenance work has been performed such that parts such as an exhaust pipe and the like are taken out from a CVD apparatus and deposits are removed from the parts thereafter. Such maintenance work creates a problem in that a worker should spend much effort and the apparatus needs to be stopped for an extended time.

### SUMMARY

According to the first aspect of the present disclosure, a method of cleaning a thin film forming apparatus is provided, where the method is for removing deposits adhering to an inside of the thin film forming apparatus after supplying a film-forming gas into a reaction chamber of the thin film forming apparatus to form a amorphous carbon film on a workpiece. The method comprises: a heating operation of heating at least one of an inside of the reaction chamber and an inside of an exhaust pipe connected to the reaction chamber to a predetermined temperature; and a removing operation of supplying a cleaning gas containing oxygen gas and hydrogen gas into at least one of the inside of the reaction chamber and the inside of the exhaust pipe heated in the heating operation, heating the cleaning gas to the predetermined temperature to activate the oxygen gas and the hydrogen gas contained in the cleaning gas, and thereafter removing the deposits adhering to the inside of the thin film forming apparatus by the oxygen gas and the hydrogen gas activated.

According to the second aspect of the present disclosure, a thin film forming method is provided where the method comprises: an amorphous carbon film forming operation of forming an amorphous carbon film on a workpiece; and a cleaning operation of cleaning a thin film forming apparatus by the method according to the first aspect of the present disclosure.

According to the third aspect of the present disclosure, a thin film forming apparatus is provided where the apparatus is for supplying a film-forming gas into a reaction chamber thereof to form an amorphous carbon film on a workpiece and for removing deposits adhering to an inside of the thin film forming apparatus by the formation of the amorphous carbon film. The apparatus comprises: a heating unit configured to heat at least one of an inside of the reaction chamber and an inside of an exhaust pipe connected to the reaction chamber to a predetermined temperature; a cleaning gas supply unit configured to supply a cleaning gas containing oxygen gas and hydrogen gas; and a control system configured to control the heating unit and the cleaning gas supply unit, wherein the control system is configured to control the cleaning gas supply unit to supply the cleaning gas containing the oxygen gas and the hydrogen gas into at least one of the inside of the reaction chamber and the inside of the exhaust pipe heated by the heating unit, the cleaning gas is heated to the predetermined temperature to activate the oxygen gas and the hydrogen gas contained in the cleaning gas, and the deposits adhering to the inside of the thin film forming apparatus are removed by the oxygen gas and the hydrogen gas thus activated.

### BRIEF DESCRIPTION OF THE DRAWINGS

The accompanying drawings, which are incorporated in and constitute a part of the specification, illustrate embodiments of the invention, and together with the general description given above and the detailed description of the embodiments given below, serve to explain the principles of the invention.

FIG. 1 is a view showing a heat treatment apparatus according to a first embodiment.

FIG. 2 is a view showing the configuration of a control system employed in the heat treatment apparatus shown in FIG. 1.

FIGS. 3A to 3F illustrate a recipe explaining a method of cleaning a thin film forming apparatus and a thin film forming method according to the first embodiment.

FIG. 4 is a view showing a heat treatment apparatus according to a second embodiment.

FIGS. 5A to 5G illustrate a recipe explaining a cleaning process according to the second embodiment.

FIGS. 6A to 6E illustrate a recipe explaining a cleaning process according to a third embodiment.

### DETAILED DESCRIPTION

Description will now be given on a method of cleaning a thin film forming apparatus, a thin film forming method, and a thin film forming apparatus according to the present disclosure.

### First Embodiment

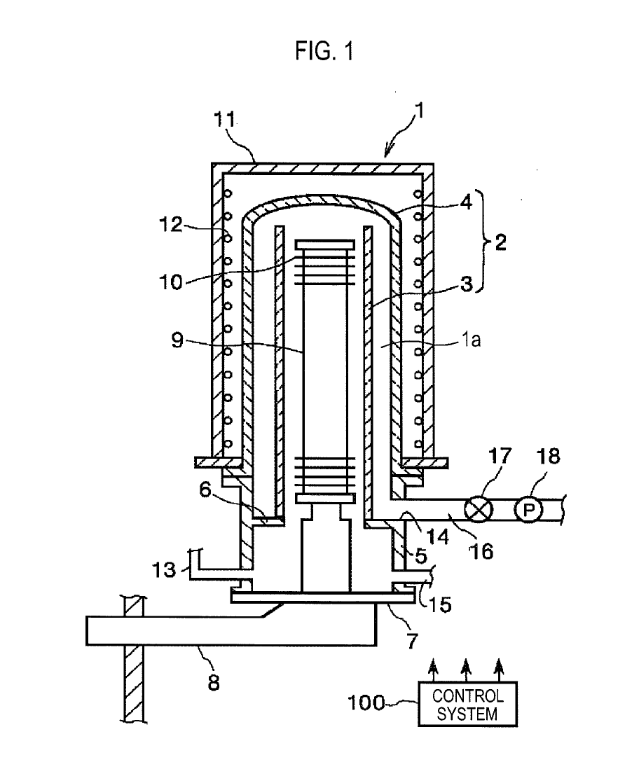

The present embodiment will be described with an example where a batch-type vertical heat treatment apparatus shown in FIG. 1 is used as a thin film forming apparatus. Moreover, the present embodiment will be described with an example where, after forming amorphous carbon films with the specified thickness on workpieces by supplying a film-forming gas from processing gas inlet pipes 13 of a heat treatment apparatus 1, the deposits adhering to the inside of the heat treatment apparatus 1 are removed by supplying a cleaning gas including oxygen (O₂) gas and hydrogen (H₂) gas from the processing gas inlet pipes 13.

Referring to FIG. 1, the heat treatment apparatus 1 includes a generally cylindrical reaction tube 2 whose longitudinal direction extends in the vertical direction. The reaction tube 2 has a double tube structure including an inner tube 3 and an outer tube 4 provided with a roof and formed to surround the inner tube 3 with a specified gap left therebetween. The inner tube 3 and the outer tube 4 are made of a material with increased heat resistance and corrosion resistance, e.g., quartz.

A tubular manifold 5 made of a stainless steel (SUS) is arranged below the outer tube 4. The manifold 5 is air-tightly connected to the lower end of the outer tube 4. The inner tube 3 is supported by a support ring 6 protruding from the inner surface of the manifold 5. The support ring 6 is integrally formed with the manifold 5.

A lid 7 is arranged below the manifold 5. The lid 7 is configured so that it can be moved up and down by a boat elevator 8. Specifically, the lower opening (throat portion) of the manifold 5 is closed if the lid 7 is moved up by the boat elevator 8, and is opened if the lid 7 is moved down by the boat elevator 8.

A wafer boat 9 made of, e.g., quartz, is placed on the lid 7. The wafer boat 9 is configured to hold a plurality of workpieces, e.g., semiconductor wafers 10, in a vertically spaced-apart relationship.

A heat insulator 11 is provided around the reaction tube 2 to surround the reaction tube 2. Temperature-elevating heaters 12 composed of, e.g., resistance heating elements are provided on the inner wall surface of the heat insulator 11. The inside of the reaction tube 2 is heated to a specified temperature by the temperature-elevating heaters 12, as a result of which the semiconductor wafers 10 are heated to a predetermined temperature.

A plurality of processing gas inlet pipes 13 is inserted through (connected to) the sidewall of the manifold 5. Only one of the processing gas inlet pipes 13 is depicted in FIG. 1. The processing gas inlet pipes 13 are arranged to face toward the inside of the inner tube 3. As shown in FIG. 1, the processing gas inlet pipes 13 are inserted through the sidewall of the manifold 5 at the lower side of the support ring 6 (or the inner tube 3).

The processing gas inlet pipes 13 are connected to a processing gas supply source (not shown) through mass flow controllers (not shown) and so forth. Therefore, a desired amount of processing gas can be supplied from the processing gas supply source into the reaction tube 2 through the processing gas inlet pipes 13. The processing gas to be supplied through the processing gas inlet pipes 13 includes a film-forming gas used to form a amorphous carbon film and a cleaning gas used to remove the deposits adhering to the inside of the heat treatment apparatus 1 during the course of forming the amorphous carbon film. Examples of the film-forming gas include ethylene (C₂H₄), isoprene (C₅H₈), propylene (C₃H₆), and acetylene (C₂H₂). Examples of the cleaning gas include a gas containing oxygen (O₂) gas, and a gas containing oxygen (O₂) gas and hydrogen (H₂) gas.

An exhaust port 14 for discharging therethrough the gas present within the reaction tube 2 is provided in the sidewall of the manifold 5. The exhaust port 14 is arranged higher than the support ring 6 to communicate with a space defined between the inner tube 3 and the outer tube 4 of the reaction tube 2. This allows the exhaust gas generated within the inner tube 3 to be discharged to the exhaust port 14 through the space defined between the inner tube 3 and the outer tube 4.

A purge gas supply pipe 15 is arranged below the exhaust port 14 to extend through the sidewall of the manifold 5. A purge gas supply source (not shown) is connected to the purge gas supply pipe 15. A desired amount of purge gas, e.g., nitrogen gas, is supplied from the purge gas supply source into the reaction tube 2 through the purge gas supply pipe 15. This purge gas acts as a diluent gas, a carrier gas of a film-forming gas in a film-forming process, a gas for adjusting concentration of active species in a cleaning operation, and a pressure adjusting gas and a returning gas for a normal pressure in a stabilizing operation and a purging operation, as will be described later.

An exhaust pipe 16 is air-tightly connected to the exhaust port 14. A valve 17 and a vacuum pump 18 are arranged along the exhaust pipe 16 in the named order from the upstream side. The valve 17 serves to regulate the opening degree of the exhaust pipe 16, thereby controlling the internal pressure of the reaction tube 2 at a predetermined value. The vacuum pump 18 serves to discharge the gas existing within the reaction tube 2 through the exhaust pipe 16, consequently regulating the internal pressure of the reaction tube 2.

An exhaust pipe heater 19 is attached around the exhaust pipe 16. The exhaust pipe heater 19 heats the inside of the exhaust tube 16 to a specified temperature. As such, in the heat treatment apparatus 1 according to the present embodiment, it is possible to set the internal temperature of the exhaust pipe 16, independently of the reaction tube 2, to the specified temperature by using the exhaust pipe heater 19.

Further, a trap and a scrubber (not shown) are arranged along the exhaust pipe 16 to detoxify the exhaust gas discharged from the reaction tube 2 before the exhaust gas is exhausted to the outside of the heat treatment apparatus 1.

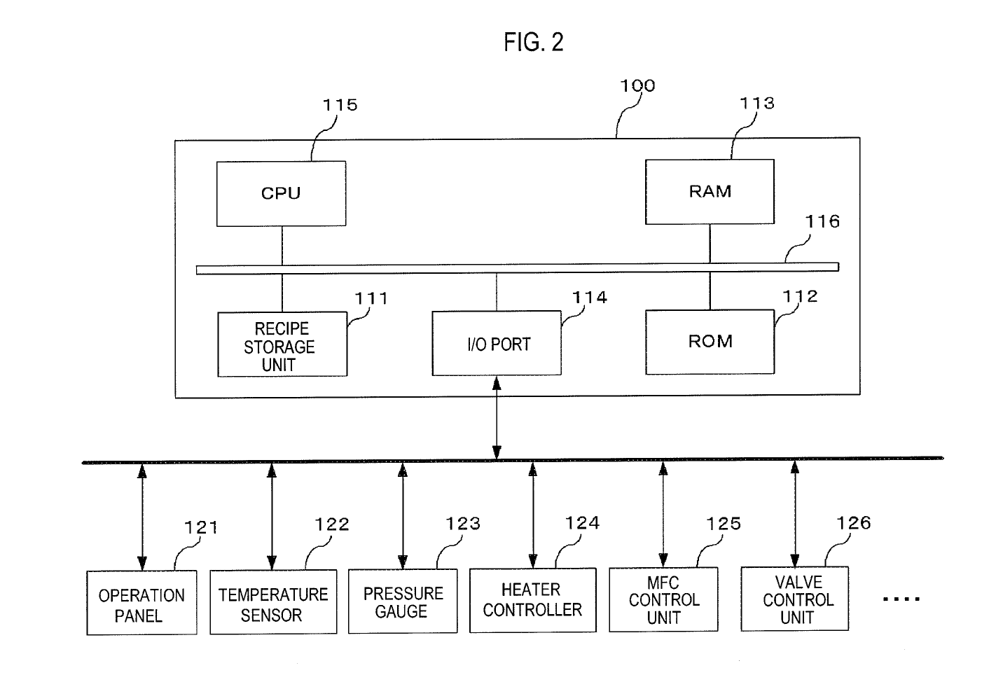

The heat treatment apparatus 1 includes a control system 100 for controlling individual units or parts of the heat treatment apparatus 1. As shown in FIG. 2, an operation panel 121, a temperature sensor (group) 122, a pressure gauge (group) 123, a heater controller 124, a MFC control unit 125 and a valve control unit 126 are connected to the control system 100.

The operation panel 121 includes a display screen and operation buttons. The operation panel 121 transfers the operation instructions of an operator to the control system 100 and allows the display screen to display various kinds of information supplied from the control system 100.

The temperature sensor (group) 122 measures the internal temperature of each of the reaction tube 2, the exhaust pipe 16 and the like, and notifies the measured temperature values to the control system 100.

The pressure gauge (group) 123 measures the internal pressure of each of the reaction tube 2 and the exhaust pipe 16 to notify the measured pressure values to the control system 100.

The heater controller 124 is designed to independently control the temperature-elevating heaters 12 and the exhaust pipe heater 19. Responding to the instructions supplied from the control system 100, the heater controller 124 energizes the temperature-elevating heaters 12 and the exhaust pipe heater 19 and causes these heaters to generate heat. The heater controller 124 measures the power consumptions of the temperature-elevating heaters 12 and the exhaust pipe heater 19 and notifies the measured power consumption to the control system 100.

The mass flow controller (MFC) control unit 125 controls MFCs (not shown) installed in the processing gas inlet pipes 13 and the purge gas supply pipe 15 such that the flow rates of the gases flowing through the MFCs become equal to the flow rates instructed by the control system 100. Further, the MFC control unit 125 measures the flow rates of the gases actually flowing through the MFCs and notifies the measured flow rates to the control system 100.

The valve control unit 126 controls the opening degrees of the valves arranged in the respective pipes according to the values instructed by the control system 100.

The control system 100 includes a recipe storage unit 111, a ROM 112, a RAM 113, an I/O port 114, a CPU 115, and a bus 116 interconnecting the foregoing parts.

The recipe storage unit 111 stores a setup recipe and a plurality of process recipes. Only the setup recipe is stored in the recipe storage unit 111 when the heat treatment apparatus 1 is manufactured first. The setup recipe is executed to generate heating models corresponding to different heat treatment apparatuses. The process recipes are prepared in a corresponding relationship with the heat treatment processes actually performed pursuant to the user's desire. For example, the process recipes define the temperature and pressure variations in the respective areas, the start and stop timing of supply of the processing gas, and the supply amount of the processing gas from the time when the semiconductor wafers 10 are loaded into the reaction tube 2 to the time when the processed semiconductor wafers 10 are unloaded from the reaction tube 2.

The ROM 112 includes an EEPROM, a flash memory, a hard disk and so forth. The ROM 112 is a storage medium for storing the operation program of the Central Processing Unit (CPU) 115. The RAM 113 serves as a work area of the CPU 115.

The I/O port 114 is connected to the operation panel 121, the temperature sensor 122, the pressure gauge 123, the heater controller 124, the MFC control unit 125 and the valve control unit 126 to control the input and output of data or signals.

The CPU 115 makes up the core of the control system 100 and executes the control program stored in the ROM 112. In response to the instructions supplied from the operation panel 121, the CPU 115 controls the operation of the heat treatment apparatus 1 in conformity with the recipes (process recipes) stored in the recipe storage unit 111. More specifically, the CPU 115 controls the temperature sensor (group) 122, the pressure gauge (group) 123, and the MFC control unit 125 to respectively measure the temperatures, the pressures, and the flow rates within the reaction tube 2, the processing gas inlet pipes 13, and the exhaust pipe 16. Based on the measured data, the CPU 115 outputs control signals to the heater controller 124, the MFC control unit 125 and the valve control unit 126 and controls the respective units or parts pursuant to the process recipes. The bus 116 transfers information between the respective units or parts.

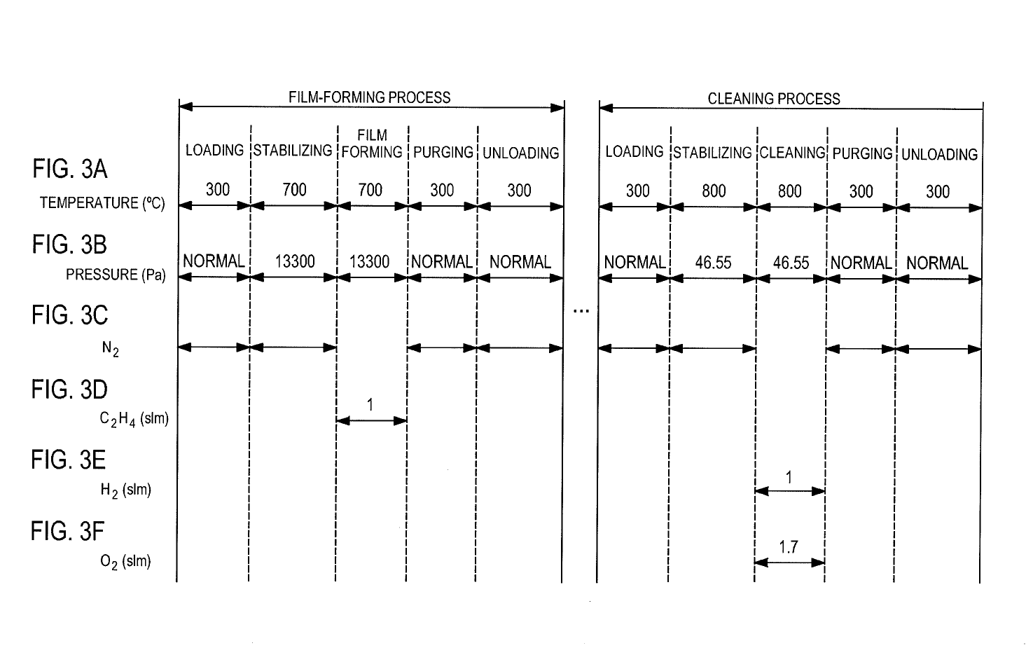

Next, description will be given on a method of cleaning a thin film forming apparatus and a thin film forming method using the heat treatment apparatus 1 configured as above. FIGS. 3A to 3F illustrate a recipe explaining the method of cleaning a thin film forming apparatus and the thin film forming method according to the present embodiment.

The present embodiment will be described with an example where a film-forming gas, e.g., ethylene (C₂H₄), is supplied from the processing gas inlet pipes 13 to form amorphous carbon films with the specified thickness on the semiconductor wafers 10 and then a cleaning gas containing oxygen (O₂) gas and hydrogen (H₂) gas is supplied from the processing gas inlet pipes 13 to remove deposits adhering to the inside of the heat treatment apparatus 1, e.g., reaction byproducts containing carbon and hydrogen.

In the following description, the operations of the respective units or parts making up the heat treatment apparatus 1 are controlled by the control system 100 (the CPU 115). As set forth above, the control system 100 (the CPU 115) controls the heater controller 124 (the temperature-elevating heaters 12, the exhaust pipe heater 19), the MFC control unit 125, the valve control unit 126, and the vacuum pump 18 such that the temperatures, the pressures, and the gas flow rates within the reaction tube 2 during the respective processes are in conformity with the conditions of the recipe shown in FIGS. 3A to 3F.

First, the internal temperature of the reaction tube 2 (the inner tube 3) is set equal to a predetermined temperature, e.g., 300° C., as shown in FIG. 3A. Moreover, as shown in FIG. 3C, a specified amount of nitrogen is supplied from the purge gas supply pipe 15 into the inner tube 3 (the reaction tube 2). Then, the wafer boat 9 holding the semiconductor wafers 10 is placed on the lid 7. Thereafter, the lid 7 is moved up by the boat elevator 8 to load the semiconductor wafers 10 (the wafer boat 9) into the reaction tube 2 (a loading operation).

Subsequently, as shown in FIG. 3C, a specified amount of nitrogen is supplied from the purge gas supply pipe 15 into the inner tube 3. The internal temperature of the reaction tube 2 is set equal to a predetermined temperature, e.g., 700° C., as shown in FIG. 3A. The gas existing within the reaction tube 2 is discharged to reduce the internal pressure of the reaction tube 2 to a predetermined pressure, e.g., 13,300 Pa (100 Torr), as shown in FIG. 3B. The inside of the reaction tube 2 is stabilized at this temperature and pressure (a stabilizing operation).

If the inside of the reaction tube 2 is stabilized at the predetermined temperature and pressure, the supply of nitrogen from the purge gas supply pipe 15 is stopped. Then, a specified amount of film-forming gas, e.g., ethylene (C₂H₄), is supplied at a flow rate of 1 slm from the processing gas inlet pipes 13 into the reaction tube 2 as shown in FIG. 3D (a film-forming operation). The ethylene supplied into the reaction tube 2 is thermally decomposed within the reaction tube 2 to form amorphous carbon films on the semiconductor wafers 10.

If the amorphous carbon films with the specified thickness are formed on the semiconductor wafers 10, the supply of the film-forming gas from the processing gas inlet pipes 13 is stopped. Subsequently, as shown in FIG. 3C, a specified amount of nitrogen is supplied from the purge gas supply pipe 15 into the inner tube 3. The internal temperature of the reaction tube 2 is set equal to a predetermined temperature, e.g., 300° C., as shown in FIG. 3A. The gas existing within the reaction tube 2 is discharged to return the internal pressure of the reaction tube 2 to a predetermined pressure, e.g., the normal pressure, as shown in FIG. 3B (a purging operation). In order to reliably discharge the gas existing within the reaction tube 2, it is preferred that the discharge of the gas from the reaction tube 2 and the supply of the nitrogen gas into the reaction tube 2 be repeated more than once.

The lid 7 is moved down by the boat elevator 8 to unload the semiconductor wafers 10 (the wafer boat 9) from the inside of the reaction tube 2 (an unloading operation). This finishes the process for forming the amorphous carbon films.

If the film-forming process is repeatedly performed more than once, compounds containing carbon and hydrogen, e.g., reaction products and reaction byproducts generated in the film-forming process, are deposited on (adhere to) not only the surfaces of the semiconductor wafers 10 but also the inner and the outer surfaces of the inner tube 3, the inner surface of the outer tube 4, and the exhaust pipe 16. Accordingly, a cleaning process for removing the deposits adhering to the inside of the heat treatment apparatus 1 is carried out after the film-forming process is performed a predetermined number of times.

First, the internal temperature of the reaction tube 2 (the inner tube 3) is set equal to a predetermined temperature, e.g., 300° C., as shown in FIG. 3A. Moreover, as shown in FIG. 3C, a specified amount of nitrogen is supplied from the purge gas supply pipe 15 into the inner tube 3 (the reaction tube 2). Then, the wafer boat 9 that does not hold the semiconductor wafers 10 is placed on the lid 7. Thereafter, the lid 7 is moved up by the boat elevator 8 to load the wafer boat 9 into the reaction tube 2 (a loading operation).

Subsequently, as shown in FIG. 3C, a specified amount of nitrogen is supplied from the purge gas supply pipe 15 into the inner tube 3. The internal temperature of the reaction tube 2 is set equal to a predetermined temperature, e.g., 800° C., as shown in FIG. 3A. The gas existing within the reaction tube 2 is discharged to reduce the internal pressure of the reaction tube 2 to a predetermined pressure, e.g., 46.55 Pa (0.35 Torr), as shown in FIG. 3B. The inside of the reaction tube 2 is stabilized at this temperature and pressure (a stabilizing operation).

In this connection, the internal temperature of the reaction tube 2 is preferably in a range of 350° C. to 900° C. and more preferably in a range of 350° C. to 800° C. If the internal temperature of the reaction tube 2 is set to fall within this range, the oxygen gas and the hydrogen gas contained in the cleaning gas are activated, thereby making it possible to effectively remove the deposits adhering to the inside of the heat treatment apparatus 1. The internal pressure of the reaction tube 2 is preferably in a range of 1.33 Pa to 2,660 Pa (0.01 Torr to 20 Torr) and more preferably in a range of 1.33 Pa to 665 Pa (0.01 Torr to 5 Torr). If the internal pressure of the reaction tube 2 is set to fall within this range, it becomes possible to remove the deposits adhering to a hard-to-remove area. It is particularly preferable to set the internal temperature of the reaction tube 2 equal to 350° C. or more, e.g., within a range of 350° C. to 900° C., while setting the internal pressure of the reaction tube 2 to a range of 1.33 Pa to 2,660 Pa (0.01 Torr to 20 Torr). If the internal temperature and the internal pressure of the reaction tube 2 are set to fall within these ranges, active species (O* active species and OH* active species) are sufficiently generated from the oxygen gas and the hydrogen gas contained in the cleaning gas, thereby making it possible to more effectively remove the deposits adhering to the inside of the heat treatment apparatus 1.

In the present embodiment, the exhaust pipe 16 is not heated by the exhaust pipe heater 19. That is, the inside of the exhaust pipe 16 is kept at the normal temperature. This is because the inside of the exhaust pipe 16 is heated by the residual heat from the reaction tube 2, the inside of which is set to a higher temperature, e.g., 800° C. It is preferable that the exhaust pipe 16 is not heated by the exhaust pipe heater 19. The internal temperature of the exhaust pipe 16 is preferably in a range of 200° C. to 400° C. and more preferably in a range of 200° C. to 300° C. By maintaining the internal temperature of the exhaust pipe 16 in the range mentioned above, the oxygen (O₂) gas and the hydrogen (H₂) gas contained in the cleaning gas are activated, thereby effectively removing the deposits adhering to the inside of the exhaust pipe 16. If the inside temperature of the exhaust pipe 16 becomes higher than the aforementioned range, members attached to the exhaust pipe 16, e.g., an O-ring may be deteriorated.

If the inside of the reaction tube 2 is stabilized at this temperature and pressure, the supply of nitrogen from the purge gas supply pipe 15 is stopped. Then, a predetermined amount of cleaning gas is supplied from the processing gas inlet pipes 13 into the reaction tube 2. For example, hydrogen (H₂) gas is supplied at a flow rate of 1 slm as shown in FIG. 3E and oxygen (O₂) gas is supplied at a flow rate of 1.7 slm as shown in FIG. 3F (a cleaning operation).

In this regard, flow rates of the oxygen (O₂) gas and the hydrogen (H₂) gas are preferably set in such a way that the multiplicative inverse of the sum of the flow rates is in a range of 0.2 to 0.5. This is because the active species concentrations of O* active species and OH* active species are raised. More preferably, flow rates of the oxygen (O₂) gas and the hydrogen (H₂) gas are set in such a way that the multiplicative inverse of the sum of the flow rates is in a range of 0.25 to 0.4 and further more preferably in a range of 0.3 to 0.35. In case of the range of 0.3 to 0.35, the active species concentrations of O* active species and OH* active species become a maximum level. In the present embodiment, since the flow rates of the oxygen (O₂) gas and the hydrogen (H₂) gas are respectively set to 1 slm and 1.7 slm as one example, the multiplicative inverse of their sum is 0.37(37%). In other words, the respective flow rates of the oxygen (O₂) gas and the hydrogen (H₂) gas are set in such a manner that the active species concentrations of O* active species and OH* active species are increased.

The cleaning gas supplied into the reaction tube 2 is heated within the inner tube 3 such that the hydrogen gas and the oxygen gas contained in the cleaning gas are activated to generate active species (O* active species and OH* active species) that are reactive free atoms. Therefore, the cleaning gas within the reaction tube 2 becomes the state of having a multiplicity of the active species. The cleaning gas containing the hydrogen gas and the oxygen gas thus activated is supplied from the inside of the inner tube 3 to the exhaust pipe 16 through the space defined between the inner tube 3 and the outer tube 4, thereby etching the deposits (the compounds containing carbon and hydrogen) adhering to the inside of the heat treatment apparatus 1, e.g., the inner and outer surfaces of the inner tube 3, the inner surface of the outer tube 4, the inner surface of the exhaust pipe 16, the wafer boat 9, and various kinds of accessories such as a heat reserving cover and the like. Accordingly, the deposits adhering to the inside of the heat treatment apparatus 1 are removed by the etching.

After removing the deposits adhering to the inside of the heat treatment apparatus 1, the supply of the cleaning gas from the processing gas inlet pipes 13 is stopped. Subsequently, as shown in FIG. 3C, a specified amount of nitrogen is supplied from the purge gas supply pipe 15 into the inner tube 3. The internal temperature of the reaction tube 2 is set equal to a predetermined temperature, e.g., 300° C., as shown in FIG. 3A. The gas existing within the reaction tube 2 is discharged to return the internal pressure of the reaction tube 2 to a predetermined pressure, e.g., the normal pressure, as shown in FIG. 3B (a purging operation). In order to reliably discharge the gas existing within the reaction tube 2, it is preferred that the discharge of the gas from the reaction tube 2 and the supply of the nitrogen gas into the reaction tube 2 be repeated more than once.

The lid 7 is moved down by the boat elevator 8 to unload the wafer boat 9 from the inside of the reaction tube 2 (an unloading operation), eventually finishing the cleaning process.

With a view to confirming the effects provided by the present embodiment, the cleaning process of the present embodiment was performed in a state that a specified amount of deposits adhere to the inside of the heat treatment apparatus 1. Then, the time taken for the deposits to be removed was measured. The measurement was conducted in the inner surface of the exhaust pipe 16 near the exhaust port 14, where the deposits are easy to adhere to but hard to be removed from. For the sake of comparison, the time taken for the deposits to be removed was measured with respect to a case (comparative example) where the same cleaning process as in the present embodiment is performed except that oxygen gas and hydrogen gas as the cleaning gas are respectively supplied at a flow rate of 1 slm and a flow rate of 0 slm with the internal pressure of the reaction tube 2 kept at 13,300 Pa (100 Torr). The result of comparison reveals that the deposits could be sufficiently removed within two hours in the present embodiment but the deposits could not be sufficiently removed even after the lapse of thirty two hours in the comparative example. This means that the cleaning process of the present embodiment is capable of sufficiently removing the deposits within a short period of time.

As described above, the present embodiment makes it possible to remove the deposits adhering to the inside of the heat treatment apparatus 1 within a short period of time. This is because the cleaning gas containing the oxygen gas and the hydrogen gas is supplied from the processing gas inlet pipes 13. Accordingly, it is possible to reduce effort required in a maintenance work while shortening a shutdown time.

### Second Embodiment

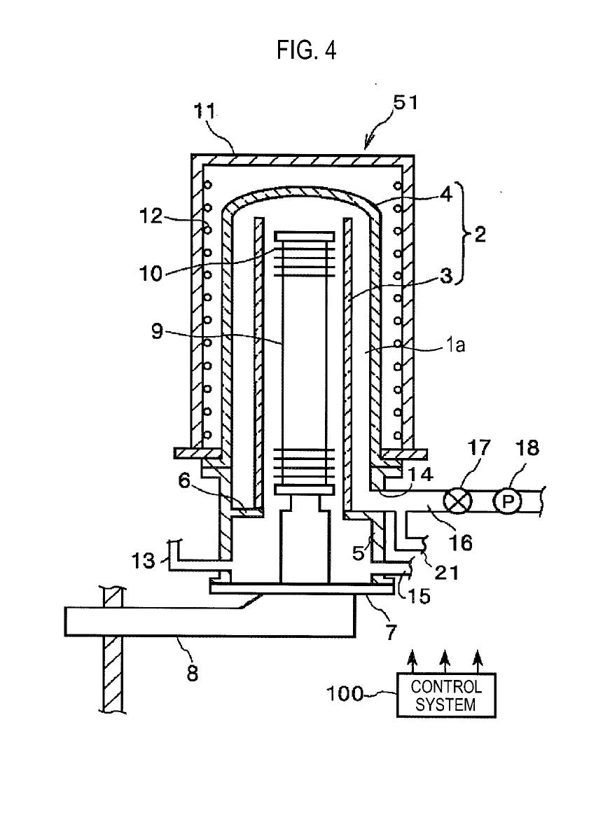

The present embodiment will be described with an example where a batch-type vertical heat treatment apparatus 51 shown in FIG. 4 is used as a thin film forming apparatus. The heat treatment apparatus 51 of the present embodiment is the same as the heat treatment apparatus 1 shown in FIG. 1, except that a cleaning gas inlet pipe 21 is connected to the exhaust pipe 16. Description will be centered on those points differing from the first embodiment. The common components or members will be designated by the same reference numerals but will not be described in detail.

Referring to FIG. 4, the heat treatment apparatus 51 includes a cleaning gas inlet pipe 21 connected to the exhaust pipe 16 thereof. The cleaning gas inlet pipe 21 is connected to the exhaust pipe 16 near the exhaust port 14. The cleaning gas inlet pipe 21 is in communication with a cleaning gas supply source (not shown) through a mass flow controller (not shown) and so forth. The mass flow controller provided in the cleaning gas inlet pipe 21 is controlled by the MFC control unit 125. The MFC control unit 125 controls the mass flow controller such that the flow rate of the cleaning gas flowing from the cleaning gas supply source to the cleaning gas inlet pipe 21 becomes equal to the flow rate instructed by the control system 100. The cleaning gas is supplied from the cleaning gas inlet pipe 21 into the exhaust pipe 16 near the exhaust port 14 and is discharged to the outside of the heat treatment apparatus 51 through the valve 17 and the vacuum pump 18. As in the first embodiment, examples of the cleaning gas include a gas containing oxygen (O₂) gas, and a gas containing oxygen (O₂) gas and hydrogen (H₂) gas. In this manner, the heat treatment apparatus 51 of the present embodiment is capable of introducing the cleaning gas into the exhaust pipe 16 independently of the processing gas inlet pipes 13.

Next, description will be given on a method of cleaning a thin film forming apparatus and a thin film forming method using the heat treatment apparatus 51 configured as above. The present embodiment will be described with an example where a cleaning process includes the first cleaning operation of supplying a cleaning gas containing oxygen (O₂) gas from the processing gas inlet pipes 13 after forming amorphous carbon films with the specified thickness on the semiconductor wafers 10 by supplying a film-forming gas, e.g., ethylene (C₂H₄), from the processing gas inlet pipes 13 and the second cleaning operation of supplying a cleaning gas containing oxygen (O₂) gas and hydrogen (H₂) gas from the cleaning gas inlet pipe 21.

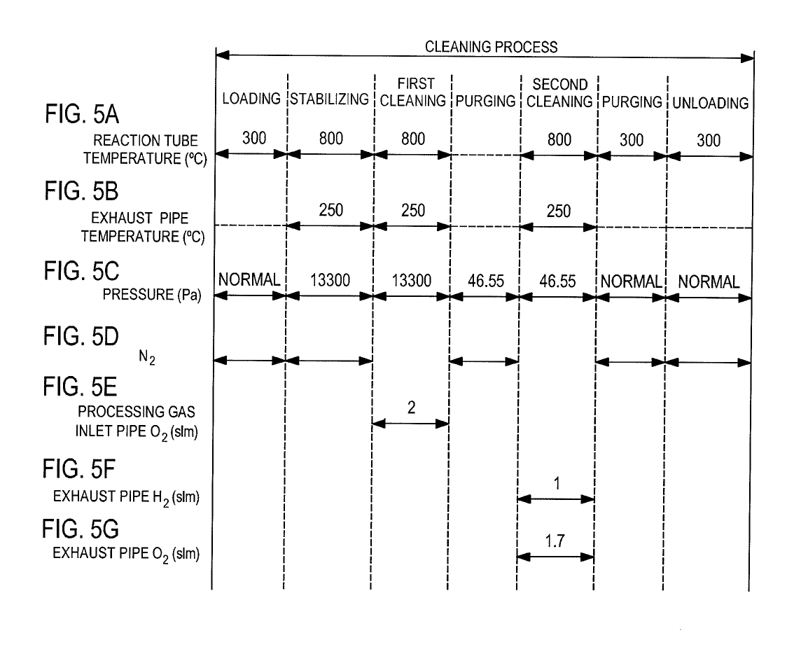

Since the film-forming process of the present embodiment is the same as that of the first embodiment, description will be made on only the cleaning process performed after the film-forming process. FIGS. 5A to 5G illustrate a recipe explaining the cleaning process according to the second embodiment.

If the film-forming process comes to an end and if the deposits adhere to the inside of the heat treatment apparatus 51, the internal temperature of the reaction tube 2 (the inner tube 3) is first set equal to a predetermined temperature, e.g., 300° C., as shown in FIG. 5A. Moreover, as shown in FIG. 5D, a specified amount of nitrogen is supplied from the purge gas supply pipe 15 into the inner tube 3 (the reaction tube 2). Then, the wafer boat 9 that does not hold the semiconductor wafers 10 is placed on the lid 7. Thereafter, the lid 7 is moved up by the boat elevator 8 to load the wafer boat 9 into the reaction tube 2 (a loading operation).

Subsequently, as shown in FIG. 5D, a specified amount of nitrogen is supplied from the purge gas supply pipe 15 into the inner tube 3. The internal temperature of the reaction tube 2 is set equal to a predetermined temperature, e.g., 800° C., as shown in FIG. 5A. The gas existing within the reaction tube 2 is discharged to reduce the internal pressure of the reaction tube 2 to a predetermined pressure, e.g., 13,300 Pa (100 Torr), as shown in FIG. 5C. The internal temperature of the exhaust pipe 16 is set equal to a predetermined temperature, e.g., 250° C., as shown in FIG. 5B. The inside of the reaction tube 2 and the inside of the exhaust pipe 16 are stabilized at this temperature and pressure (a stabilizing operation).

In this connection, the internal temperature of the reaction tube 2 is preferably in a range of 350° C. to 900° C. and more preferably in a range of 350° C. to 800° C. The internal pressure of the reaction tube 2 is preferably in a range of 665 Pa (5 Torr) to a normal pressure. If the internal temperature and the internal pressure of the reaction tube 2 are set to fall within these ranges, the oxygen gas contained in the cleaning gas is activated, thereby making it possible to remove the deposits adhering to the inside of the heat treatment apparatus 51. The exhaust pipe 16 where the deposits are easy to adhere to but hard to be removed from is cleaned by the cleaning gas supplied from the cleaning gas inlet pipe 21. This eliminates the need to keep the internal pressure of the reaction tube 2 low.

The internal temperature of the exhaust pipe 16 is preferably in a range of 200° C. to 400° C. and more preferably in a range of 200° C. to 300° C. If the internal temperature of the reaction tube 2 is set to fall within this range, the oxygen gas and the hydrogen gas contained in the cleaning gas are activated, making it possible to effectively remove the deposits adhering to the inside of the exhaust pipe 16. If the internal temperature of the exhaust pipe 16 is kept higher than the above range, the members attached to the exhaust pipe 16, such as an O-ring and the like, may suffer from degradation.

If the inside of the reaction tube 2 and the inside of the exhaust pipe 16 are stabilized at the predetermined temperatures and pressures, the supply of nitrogen from the purge gas supply pipe 15 is stopped. Then, a predetermined amount of cleaning gas is supplied from the processing gas inlet pipes 13 into the reaction tube 2. For example, oxygen (O₂) gas is supplied at a flow rate of 2 slm as shown in FIG. 5E (a first cleaning operation).

The cleaning gas supplied into the reaction tube 2 is heated within the inner tube 3. Thus, the oxygen gas contained in the cleaning gas is activated so that the deposits (the compounds containing carbon and hydrogen) adhering to the inside of the reaction tube 2, e.g., the inner surface of the inner tube 3, can be etched by the cleaning gas containing the activated oxygen gas.

If the deposits adhering to the inside of the reaction tube 2 such as the inside of the inner tube 3 are removed, the supply of the cleaning gas from the processing gas inlet pipes 13 is stopped. Subsequently, the gas existing within the reaction tube 2 is discharged and, as shown in FIG. 5D, a specified amount of nitrogen is supplied from the purge gas supply pipe 15 into the inner tube 3 to set the internal pressure of the reaction tube 2 at a predetermined pressure, e.g., 46.55 Pa (0.35 Torr), as shown in FIG. 5C (a purging operation). In order to reliably discharge the gas existing within the reaction tube 2, it is preferred that the discharge of the gas from the reaction tube 2 and the supply of the nitrogen gas into the reaction tube 2 be repeated more than once.

In this connection, the internal pressure of the reaction tube 2 (or the exhaust pipe 16) is preferably set within a range of 1.33 Pa to 2,660 Pa (0.01 Torr to 20 Torr). If the internal pressure is set to fall within this range, active species (O* active species and OH* active species) are easily generated from the oxygen gas and the hydrogen gas contained in the cleaning gas, thereby making it possible to effectively remove the deposits adhering to the inside of the exhaust pipe 16.

Then, the supply of nitrogen from the purge gas supply pipe 15 is stopped and a predetermined amount of cleaning gas is supplied from the cleaning gas inlet pipe 21 into the exhaust pipe 16. For example, hydrogen (H₂) gas is supplied at a flow rate of 1 slm as shown in FIG. 5F and oxygen (O₂) gas is supplied at a flow rate of 1.7 slm as shown in FIG. 5G (a second cleaning operation).

The cleaning gas supplied into the exhaust pipe 16 is heated within the exhaust pipe 16 to activate the hydrogen gas and the oxygen gas contained therein. Thus, the containing gas within the exhaust pipe 16 becomes the state of having a multiplicity of active species (O* active species and OH* active species). Accordingly, the deposits (the compounds containing carbon and hydrogen) adhering to the inner surface of the exhaust pipe 16, from which the deposits are hard to be removed, can be etched by the cleaning gas containing these active species. As a result, the deposits adhering to the inside of the heat treatment apparatus 51 are sufficiently removed.

After removing the deposits adhering to the inside of the heat treatment apparatus 51, the supply of the cleaning gas from the cleaning gas inlet pipe 21 is stopped. Subsequently, as shown in FIG. 5D, a specified amount of nitrogen is supplied from the purge gas supply pipe 15 into the inner tube 3. The internal temperature of the reaction tube 2 is set equal to a predetermined temperature, e.g., 300° C., as shown in FIG. 5A. The gas existing within the reaction tube 2 is discharged to return the internal pressure of the reaction tube 2 to a predetermined pressure, e.g., the normal pressure, as shown in FIG. 5C (a purging operation). In order to reliably discharge the gas existing within the reaction tube 2, it is preferred that the discharge of the gas from the reaction tube 2 and the supply of the nitrogen gas into the reaction tube 2 be repeated more than once.

The lid 7 is moved down by the boat elevator 8 to unload the wafer boat 9 from the inside of the reaction tube 2 (an unloading operation), eventually finishing the cleaning process.

As described above, the cleaning process according to the present embodiment includes the first cleaning operation in which the deposits adhering to the inside of the reaction tube 2 are removed by supplying a cleaning gas containing oxygen gas from the processing gas inlet pipes 13 and the second cleaning operation in which the deposits adhering to the inside of the exhaust pipe 16 are removed by supplying a cleaning gas containing oxygen gas and hydrogen gas from the cleaning gas inlet pipe 21. This makes it possible to sufficiently remove the deposits adhering to the inside of the heat treatment apparatus 51 within a short period of time. Accordingly, it is possible to reduce effort required in a maintenance work while shortening a shutdown time.

While the present embodiment has been described with an example where the second cleaning operation of removing the deposits adhering to the inside of the exhaust pipe 16 is performed after the first cleaning operation of removing the deposits adhering to the inside of the reaction tube 2, and the first cleaning operation and the second cleaning operation may be performed at the same time. In this case, it becomes possible to effectively remove the deposits adhering to the inside of the heat treatment apparatus 51 within a further reduced period of time.

### Third Embodiment

The present embodiment will be described with an example where, as in the second embodiment, the batch-type vertical heat treatment apparatus 51 shown in FIG. 4 is used as a thin film forming apparatus. Moreover, the present embodiment will be described with an example where, after forming amorphous carbon films with the specified thickness on the semiconductor wafers 10 by supplying a film-forming gas, e.g., ethylene (C₂H₄), from the processing gas inlet pipes 13, a cleaning gas containing oxygen (O₂) gas and hydrogen (H₂) is supplied from the cleaning gas inlet pipe 21, with no cleaning gas supplied from the processing gas inlet pipes 13, to remove the deposits adhering to the inside of the exhaust pipe 16, e.g., the reaction byproducts containing carbon and hydrogen. In other words, the present embodiment will be described with an example of removing the deposits adhering to the inside of the exhaust pipe 16 where the deposits are easy to adhere to but hard to be removed from.

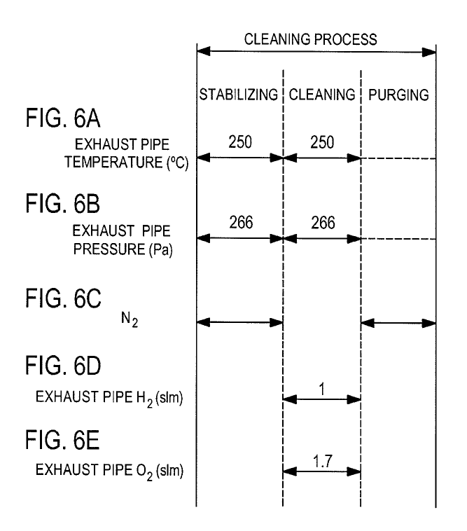

In the present embodiment, the heat treatment apparatus 51 of the second embodiment is used and the film-forming process of the present embodiment is the same as that of the first embodiment. Therefore, description will be made on the cleaning process performed after the film-forming process. FIGS. 6A to 6E illustrate a recipe explaining the cleaning process according to the present embodiment.

If the film-forming process comes to an end and if the deposits adhere to the inside of the heat treatment apparatus 51, the lid 7 is moved up by the boat elevator 8 to bring the furnace throat into a closed state. In this state, a specified amount of nitrogen is supplied from the purge gas supply pipe 15 into the inner tube 3 as shown in FIG. 6C. The internal temperature of the exhaust pipe 16 is set equal to a predetermined temperature, e.g., 250° C., as shown in FIG. 6A. The internal pressure of the exhaust pipe 16 is reduced to a predetermined pressure, e.g., 266 Pa (2 Torr), as shown in FIG. 6B. The inside of the exhaust pipe 16 is stabilized at this temperature and pressure (a stabilizing operation).

As in the second embodiment, the internal temperature of the exhaust pipe 16 is preferably in a range of 200° C. to 400° C. and more preferably in a range of 200° C. to 300° C. Just like the second embodiment, the internal pressure of the exhaust pipe 16 is preferably in a range of 1.33 Pa to 2,660 Pa (0.01 Torr to 20 Torr) and more preferably in a range of 13.3 Pa to 400 Pa (0.1 Torr to 3 Torr).

If the inside of the exhaust pipe 16 is stabilized at the predetermined temperature and pressure, the supply of nitrogen from the purge gas supply pipe 15 is stopped. Then, a predetermined amount of cleaning gas is supplied from the cleaning gas inlet pipe 21 into the exhaust pipe 16. For example, hydrogen (H₂) gas is supplied at a flow rate of 1 slm as shown in FIG. 6D and oxygen (O₂) gas is supplied at a flow rate of 1.7 slm as shown in FIG. 6E (a cleaning operation).

The cleaning gas supplied into the exhaust pipe 16 is heated within the exhaust pipe 16 to activate therein. Thus, the containing gas within the exhaust pipe 16 becomes the state of having a multiplicity of active species (O* active species and OH* active species). Accordingly, the hydrogen gas and the oxygen gas contained in the cleaning gas are activated so that the deposits (the compounds containing carbon and hydrogen) adhering to the inner surface of the exhaust pipe 16 where the deposits are easy to adhere to but hard to be removed from can be etched by the cleaning gas containing these active species. As a result, the deposits adhering to the exhaust pipe 16 are effectively removed.

After removing the deposits adhering to the inside of the exhaust pipe 16, the supply of the cleaning gas from the cleaning gas inlet pipe 21 is stopped. Subsequently, as shown in FIG. 6C, a specified amount of nitrogen is supplied into the inner tube 3 from the purge gas supply pipe 15. The internal temperature of the reaction tube 2 is set equal to a predetermined temperature. The gas existing within the reaction tube 2 is discharged and the internal pressure of the reaction tube 2 and the exhaust pipe 16 is returned to a normal pressure (a purging operation), eventually finishing the cleaning process.

In the present embodiment, the wafer boat 9 holding the semiconductor wafers 10 is placed on the lid 7 and loaded into the reaction tube 2. Consequently, the film-forming process for forming amorphous carbon films on the semiconductor wafers 10 can be performed in a state that no deposit adheres to the inside of the exhaust pipe 16 to which deposits are easy to adhere. This reduces the number of times of cleaning the inside of the reaction tube 2, which in turn decreases effort in a maintenance work and shortens a shutdown time.

With the present embodiment described above, the cleaning gas containing oxygen gas and hydrogen gas is supplied from the cleaning gas inlet pipe 21. This makes it possible to effectively remove the deposits adhering to the inside of the exhaust pipe 16 within a short period of time. Accordingly, it is possible to reduce effort required in a maintenance work while shortening a shutdown time.

The present disclosure is not limited to the embodiments described above but may be modified or applied in many different forms. Other embodiments applicable to the present disclosure will be described below.

In the first embodiment, the cleaning gas containing oxygen gas and hydrogen gas is supplied from the processing gas inlet pipes 13. In the second embodiment, the cleaning gas containing oxygen gas is supplied from the processing gas inlet pipes 13 and the cleaning gas containing oxygen gas and hydrogen gas is supplied from the cleaning gas inlet pipe 21. In the third embodiment, the cleaning gas containing oxygen gas and hydrogen gas is supplied from the cleaning gas inlet pipe 21. Unlike these embodiments, the cleaning gas containing oxygen gas and hydrogen gas may be supplied from one of the processing gas inlet pipes 13 and the cleaning gas inlet pipe 21 and another cleaning gas capable of removing the deposits may be supplied from the other one. In this case, it is possible to efficiently remove the deposits adhering to the inside of the heat treatment apparatus.

In the embodiments described above, hydrogen gas is supplied at a flow rate of 1 slm and oxygen gas is supplied at a flow rate of 1.7 slm when supplying the cleaning gas containing oxygen gas and hydrogen gas. As an alternative example, the cleaning gas may contain a diluent gas formed of an inert gas such as nitrogen.

In the third embodiment, the cleaning process is performed after the film-forming process. As an alternative example, the cleaning gas may be supplied from the cleaning gas inlet pipe 21 into the exhaust pipe 16 during the film-forming process. In this case, the deposits adhering to the inside of the exhaust pipe 16 to which deposits are easy to adhere can be removed while forming amorphous carbon films on the semiconductor wafers 10.

In the embodiments described above, ethylene is used as the film-forming gas. Alternatively, other gases such as isoprene (C₅H₈), propylene (C₃H₆), and acetylene (C₂H₂) may be used as long as they can form amorphous carbon films.

In the embodiments described above, the batch-type vertical heat treatment apparatus having a double tube structure is used as the heat treatment apparatus. As an alternative example, the present disclosure may be applied to a batch-type vertical heat treatment apparatus having a single tube structure or a single-wafer heat treatment apparatus.

The control system 100 employed in the embodiments of the present disclosure can be also realized using a typical computer system instead of a dedicated control system. For example, the control system 100 for performing the afore-mentioned processes can be configured by installing programs for execution of the processes into a general-purpose computer through the use of a recording medium (e.g., a flexible disk or a CD-ROM) storing the programs.

The programs can be provided by an arbitrary means. The programs may be provided not only by the recording medium mentioned above but also through a communication line, a communication network, a communication system or the like. In the latter case, the programs may be posted on bulletin boards (BBS) and provided through a network together with carrier waves. The program thus provided is started up and executed in the same manner as other application programs under the control of an operating system, thereby performing the processes described above.

The present disclosure can find its application in a method of cleaning a thin film forming apparatus for forming an amorphous carbon film, a thin film forming method, and a thin film forming apparatus.

According to the present disclosure, it is possible to reduce effort required in a maintenance work and shorten a shutdown time.

While certain embodiments have been described, these embodiments have been presented by way of example only, and are not intended to limit the scope of the disclosures. Indeed, the novel methods and apparatuses described herein may be embodied in a variety of other forms; furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of cleaning a thin film forming apparatus, for removing deposits adhering to an inside of the thin film forming apparatus after supplying a film-forming gas into a reaction chamber of the thin film forming apparatus to form a amorphous carbon film on a workpiece, the method comprising:
a heating operation of heating at least one of an inside of the reaction chamber and an inside of an exhaust pipe connected to the reaction chamber to a predetermined temperature; and
a removing operation of supplying a cleaning gas containing oxygen gas and hydrogen gas into at least one of the inside of the reaction chamber and the inside of the exhaust pipe heated in the heating operation, heating the cleaning gas to the predetermined temperature to activate the oxygen gas and the hydrogen gas contained in the cleaning gas, and thereafter removing the deposits adhering to the inside of the thin film forming apparatus by the oxygen gas and the hydrogen gas activated.

2. The method of claim 1, wherein the heating operation includes heating the inside of the reaction chamber to the predetermined temperature and the removing operation includes setting an internal pressure of the reaction chamber in a range of 1.33 Pa to 2660 Pa.

3. The method of claim 2, wherein the heating operation includes heating the inside of the reaction chamber to 350° C. to 900° C.

4. The method of claim 1, wherein the heating operation includes heating the inside of the exhaust pipe to the predetermined temperature and the removing operation includes setting an internal pressure of the exhaust pipe in a range of 1.33 Pa to 2660 Pa.

5. The method of claim 4, wherein the heating operation includes heating the inside of the exhaust pipe to 200° C. to 400° C.

6. A thin film forming method in a thin film forming apparatus, comprising:
an amorphous carbon film forming operation of forming an amorphous carbon film on a workpiece;
a heating operation of heating at least one of an inside of a reaction chamber and an inside of an exhaust pipe connected to the reaction chamber to a predetermined temperature; and
a removing operation of supplying a cleaning gas containing oxygen gas and hydrogen gas into at least one of the inside of the reaction chamber and the inside of the exhaust pipe heated in the heating operation, heating the cleaning gas to the predetermined temperature to activate the oxygen gas and the hydrogen gas contained in the cleaning gas, and thereafter removing the deposits adhering to the inside of the thin film forming apparatus by the oxygen gas and the hydrogen gas activated.

7. The method of claim 6, wherein the heating operation includes heating the inside of the reaction chamber to the predetermined temperature and the removing operation includes setting an internal pressure of the reaction chamber in a range of 1.33 Pa to 2660 Pa.

8. The method of claim 7, wherein the heating operation includes heating the inside of the reaction chamber to 350° C. to 900° C.

9. The method of claim 6, wherein the heating operation includes heating the inside of the exhaust pipe to the predetermined temperature and the removing operation includes setting an internal pressure of the exhaust pipe in a range of 1.33 Pa to 2660 Pa.

10. The method of claim 9, wherein the heating operation includes heating the inside of the exhaust pipe is heated to 200° C. to 400° C.

11. A thin film forming apparatus for supplying a film-forming gas into a reaction chamber thereof to form an amorphous carbon film on a workpiece and for removing deposits adhering to an inside of the thin film forming apparatus by the formation of the amorphous carbon film, comprising:
a heating unit configured to heat at least one of an inside of the reaction chamber and an inside of an exhaust pipe connected to the reaction chamber to a predetermined temperature;
a cleaning gas supply unit configured to supply a cleaning gas containing oxygen gas and hydrogen gas; and
a control system configured to control the heating unit and the cleaning gas supply unit, the control system being configured to control the cleaning gas supply unit to supply the cleaning gas containing oxygen gas and hydrogen gas into at least one of the inside of the reaction chamber and the inside of the exhaust pipe heated by the heating unit, the cleaning gas being heated to the predetermined temperature to activate the oxygen gas and the hydrogen gas contained in the cleaning gas, the deposits adhering to the inside of the thin film forming apparatus being removed by the oxygen gas and the hydrogen gas thus activated.

12. The apparatus of claim 11, wherein the deposits are compounds containing carbon and hydrogen.

13. The apparatus of claim 11, further comprising:
a reaction chamber pressure setting unit configured to set an internal pressure of the reaction chamber at a predetermined pressure, wherein the heating unit is configured to heat the inside of the reaction chamber to a range of 350° C. to 900° C., and the reaction chamber pressure setting unit is configured to set the internal pressure of the reaction chamber in a range of 1.33 Pa to 2660 Pa.

14. The apparatus of claim 11, further comprising:
an exhaust pipe pressure setting unit configured to set an internal pressure of the exhaust pipe at a predetermined pressure, wherein the heating unit is configured to heat the inside of the exhaust pipe to a range of 200° C. to 400° C., and the exhaust pipe pressure setting unit is configured to set the internal pressure of the exhaust pipe in a range of 1.33 Pa to 2660 Pa.
